(19) United States
(12) Patent Application Publication
(10) Pub. No.: US 2010/0207175 A1
(43) Pub. Date: Aug. 19, 2010

(54) SEMICONDUCTOR TRANSISTOR DEVICE HAVING AN ASYMMETRIC EMBEDDED STRESSOR CONFIGURATION, AND RELATED MANUFACTURING METHOD

(75) Inventors: Sushant SURYAGANDH, Sunnyvale, CA (US); Ciby THURUTHIYIL, Fremont, CA (US); Kaveri MATHUR, Austin, TX (US)

Correspondence Address: Ingrassia Fisher & Lorenz, P.C. (GF), 7010 E. Cochise Rd., Scottsdale, AZ, 85253, US

(73) Assignee: ADVANCED MICRO DEVICES, INC., Austin, TX (US)

(21) Appl. No.: 12/371,846

(22) Filed: Feb. 16, 2009

(51) Int. Cl. H01L 29/78; H01L 21/336

(52) U.S. Cl. 257/288; 438/299; 257/E21.409; 257/E29.255

(57) ABSTRACT

A semiconductor transistor device is provided. The transistor device includes a layer of semiconductor material, a gate structure overlying the layer of semiconductor material, a source region in the layer of semiconductor material, and a drain region in the layer of semiconductor material. The source region has a stress-inducing semiconductor material located therein, while the drain region is free of any stress-inducing semiconductor material. This asymmetric arrangement of stress-inducing elements results in relatively high source-body leakage, and relatively low drain-body leakage, which is beneficial in analog circuit applications.

### TECHNICAL FIELD

Embodiments of the subject matter described herein relate generally to semiconductor devices. More particularly, embodiments of the subject matter relate to a semiconductor transistor having an embedded stress element for the source region and having no embedded stress element for the drain region.

### BACKGROUND

The prior art is replete with different techniques and processes for fabricating semiconductor devices such as metal oxide semiconductor (MOS) transistors. In accordance with typical fabrication techniques, a MOS transistor is formed by creating a device structure on a semiconductor substrate, where the device structure includes a gate stack formed on a layer of semiconductor material, and source and drain regions formed in the semiconductor material to define a channel region under the gate stack. In addition, embedded strain elements (i.e., doped or undoped semiconductor material that imparts longitudinal stress on the channel region) can be used to improve the performance of MOS transistors. The conventional approach is to form embedded strain elements on both sides of the channel region: some of the stress-inducing material is located in the source region and some of the stress-inducing material is located in the drain region. The conventional approach (symmetric strain elements on both sides of the gate region) is particularly beneficial in digital circuit applications.

### BRIEF SUMMARY

An exemplary embodiment of a semiconductor transistor device includes a layer of semiconductor material having a channel region defined therein, a gate structure overlying the channel region, a source region in the layer of semiconductor material, a drain region in the layer of semiconductor material, the channel region located between the source region and the drain region, a source recess formed in the layer of semiconductor material and located in the source region, and a stress-inducing semiconductor material located in the source recess. The stress-inducing semiconductor material is only located in the source region, and the drain region is void of the stress-inducing semiconductor material.

A method of fabricating a semiconductor device is also provided. The method involves the formation of a gate structure overlying a layer of semiconductor material, the formation of spacers adjacent sidewalls of the gate structure, and the formation of a source region and a drain region in the layer of semiconductor material. The method continues by creating a source recess in the layer of semiconductor material corresponding to the source region without creating a drain recess in the layer of semiconductor material corresponding to the drain region. The method proceeds by at least partially filling the source recess with a stress-inducing semiconductor material.

An exemplary embodiment of a semiconductor transistor device is also provided. The device includes a layer of semiconductor material, a gate structure overlying the layer of semiconductor material, a source region in the layer of semiconductor material, the source region comprising a stress-inducing semiconductor material, and a drain region in the layer of semiconductor material, the drain region being free of the stress-inducing semiconductor material.

This summary is provided to introduce a selection of concepts in a simplified form that are further described below in the detailed description. This summary is not intended to identify key features or essential features of the claimed subject matter, nor is it intended to be used as an aid in determining the scope of the claimed subject matter.

### BRIEF DESCRIPTION OF THE DRAWINGS

A more complete understanding of the subject matter may be derived by referring to the detailed description and claims when considered in conjunction with the following figures, wherein like reference numbers refer to similar elements throughout the figures.

FIG. 1 is a simplified cross sectional view of an exemplary embodiment of a semiconductor transistor device that has a stress-inducing element in the source region and no stress-inducing element in the drain region; and

FIGS. 2-9 are cross sectional views that illustrate an exemplary MOS transistor device structure and a method of fabricating it.

### DETAILED DESCRIPTION

The following detailed description is merely illustrative in nature and is not intended to limit the embodiments of the subject matter or the application and uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, brief summary or the following detailed description.

For the sake of brevity, conventional techniques related to semiconductor device fabrication may not be described in detail herein. Moreover, the various tasks and process steps described herein may be incorporated into a more comprehensive procedure or process having additional steps or functionality not described in detail herein. In particular, various steps in the manufacture of semiconductor based transistors are well known and so, in the interest of brevity, many conventional steps will only be mentioned briefly herein or will be omitted entirely without providing the well known process details.

The techniques and technologies described herein may be utilized to fabricate MOS transistor devices, including NMOS transistor devices, PMOS transistor devices, and CMOS transistor devices. Although the term “MOS device” properly refers to a device having a metal gate electrode and an oxide gate insulator, that term will be used throughout to refer to any semiconductor device that includes a conductive gate electrode (whether metal or other conductive material) that is positioned over a gate insulator (whether oxide or other insulator) which, in turn, is positioned over a semiconductor substrate.

MOS transistor devices can be utilized for various analog applications and circuits, such as bandgap reference, sense amplifiers, voltage regulators, current mirrors, hypertransport, phase locked loop (PLL) circuits, input/output (I/O) circuits, etc. Embedded stress-inducing material usually increases p-n junction leakage. Such leakage, while tolerable in most digital applications, can adversely affect performance of analog and input/output devices. Floating Body (FB) devices are extensively used in PLL, I/O and hypertransport circuits in silicon-on-insulator (SOI) technology. FB devices exhibit hysteresis—time and state dependent delay behavior. In general, lower hysteresis is desired, because higher positive or negative hysteresis can shrink or stretch the clock-pulse in a propagation chain. Hysteresis depends on the ability to store change in the neutral body region. The balance of source-body, drain-body, and gate-to-body current and source-body, drain-body, and gate-to-body capacitance, in turn, determines this charge. Increasing source-drain leakage is one way to reduce hysteresis.

The semiconductor transistor devices described herein take advantage of the p-n junction leakage phenomena to improve performance of analog circuits and applications. More specifically, the semiconductor transistor devices described herein includes a stress-inducing element (or elements) that imparts more stress from the source region than the drain region. In preferred embodiments, stress-inducing material is only utilized in the source region, and the drain region remains free of stress-inducing material. In alternate embodiments, the stress-inducing material on the source side may be shaped or sized, or it may have a certain composition, such that it imparts more stress to the channel region, relative to that imparted by the stress-inducing material on the drain side.

During operation, a semiconductor transistor device having stress-inducing material only in the source region will experience relatively high source-body junction leakage and relatively low drain-body junction leakage. This characteristic can be important for purposes of hysteresis estimation of a circuit. In this regard, the source-body diode is forward biased in a partially depleted MOSFET circuit. The asymmetric effect in the source and drain side diodes reduces the hysteresis in the circuit. A leaky forward biased source-body diode lowers the body voltage for a given drain-body and gate-body current and, hence, reduces hysteresis. Moreover, the absence of a stress-inducing element in the drain region of the MOS transistor results in reduced carrier mobility on the drain side (relative to the source side). Lower mobility in the drain region results in a higher saturation electric field for a given saturation velocity. The higher saturation electric field also results in increased output resistance, which is desirable for analog circuit applications. A higher electric field lowers the channel pinch-off region for given drain and gate biases and, hence, increases output resistance.

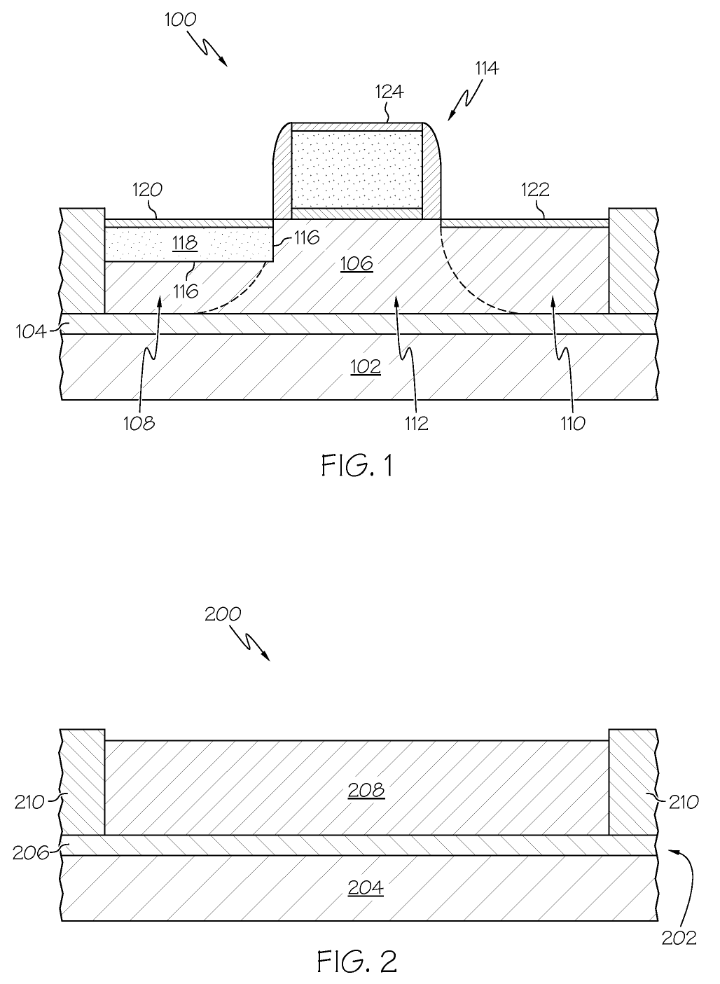

The semiconductor transistor devices described herein employ a structure having an asymmetric configuration of embedded strain elements flanking the gate region. In preferred embodiments, only a source-side strain element is used, and no stress-inducing material is located in the drain region. In this regard, FIG. 1 is a simplified cross sectional view of an exemplary embodiment of a semiconductor transistor device 100 that has a stress-inducing element in the source region and no stress-inducing element in the drain region. Although not a requirement, this particular embodiment of device 100 is formed on a silicon-on-insulator (SOI) substrate, which includes a support substrate 102, an insulator layer 104 on support substrate 102, and a layer of semiconductor material 106 on insulator layer 104. Semiconductor material 106 is preferably a silicon material as typically used in the semiconductor industry, e.g., relatively pure silicon as well as silicon admixed with other elements such as germanium, carbon, and the like. Alternatively, semiconductor material 106 can be germanium, gallium arsenide, or the like. Semiconductor material 106 can be either N-type or P-type, but is typically P-type, with wells of the appropriate type formed therein. Although the following description relates to an SOI implementation, alternate embodiments can be formed using a bulk semiconductor substrate, as is well known.

Device 100 generally includes a source region 108 formed or otherwise defined in semiconductor material 106, a drain region 110 formed or otherwise defined in semiconductor material 106, and a channel region 112 formed or otherwise defined in semiconductor material 106. Device 100 also includes a suitably configured gate structure 114 overlying semiconductor material 106. In accordance with conventional fabrication techniques and processes, channel region 112 is located between source region 108 and drain region 110, and gate structure 114 overlies channel region 112. Notably, device 100 includes a source recess 116 formed in semiconductor material 106, but it does not include a corresponding drain recess. Source recess 116 is located in source region 108, and FIG. 1 depicts source recess 116 as a cavity having a rectangular cross section.

Source recess 116 is formed to accommodate an appropriate stress-inducing semiconductor material 118. As shown in FIG. 1, stress-inducing semiconductor material 118 is located in source recess 116. Thus, source region 108 includes or is at least partially defined by stress-inducing semiconductor material 118. In contrast, drain region 110 is free of any stress-inducing semiconductor material (or the amount of stress-inducing semiconductor material in drain region 110 is considerably less than the amount in source region 108). In preferred embodiments, drain region 110 is completely void of the stress-inducing semiconductor material. As described in more detail below, stress-inducing semiconductor material 118 can be an epitaxially grown silicon material, which may be undoped or in-situ doped. For example, if device 100 is a PMOS transistor device, then the epitaxially grown silicon material might be silicon germanium, which imparts a compressive longitudinal stress to channel region 112. On the other hand, if device 100 is an NMOS transistor device, then the epitaxially grown silicon material might be silicon carbon, which imparts a tensile longitudinal stress to channel region 112. In either implementation, drain region 110 imparts little or no longitudinal stress to channel region 112. The asymmetric stressing of channel region 112 caused by stress-inducing semiconductor material 118 increases source-to-body junction leakage of device 100, relative to its drain-to-body leakage. As mentioned above, this action can be beneficial in analog circuit applications that include transistors arranged in this manner.

In accordance with typical semiconductor transistor implementations, device 100 includes silicide contact areas 120, 122, 124 for source region 108, drain region 110, and gate structure 114, respectively. These silicide contact areas 120, 122, 124 are electrically conductive elements that can be used to provide bias and/or operating voltages to device 100. Although not shown in FIG. 1, device 100 will include other features, structures, and elements that are normally fabricated during back end manufacturing processes. These well-known features, structures, and elements will not be described in detail here.

FIGS. 2-9 are cross sectional views that illustrate an exemplary MOS transistor device structure 200 and a method of fabricating it—MOS transistor device structure 200 may ultimately take the form of an PMOS transistor device or an NMOS transistor device. That said, the following description focuses on a PMOS implementation. The illustrated process can be utilized to manufacture device 100 (see FIG. 1). The semiconductor device manufacturing process described herein is suitable for use with 45 nm node technology, 32 nm node technology, and beyond, however, the use of such node technologies is not a requirement. The description of well known and conventional steps related to the fabrication of semiconductor devices may be briefly summarized or omitted entirely without providing the well known process details.

Referring to FIG. 2, the manufacture of asymmetrically stressed MOS transistors may begin by providing a semiconductor substrate 202 in and on which such transistors are fabricated. The initial steps in the fabrication of device structure 200 are conventional and will not be described in detail here. Semiconductor substrate 202 is preferably a silicon substrate, although those of skill in the semiconductor art will appreciate that other semiconductor materials could be used. Semiconductor substrate 202 may be a bulk silicon wafer (not illustrated), or preferably is an SOI substrate having a carrier or support substrate 204, an insulating layer 206, and a layer of semiconductor material 208. Semiconductor material 208 typically has a thickness of less than about 100 nanometers (nm), depending on the circuit function being implemented. In practice, semiconductor material 208 can be P-type impurity doped silicon. Insulating layer 206, which is typically silicon dioxide, preferably has a thickness of about 50-200 nm.

Isolation regions 210 are formed that extend through semiconductor material 208 to insulating layer 206. Isolation regions 210 are preferably formed by well-known shallow trench isolation (STI) techniques. Isolation regions 210 provide electrical isolation, as needed, between various devices of the circuit that are to be formed in semiconductor material 208. Either before or preferably after fabrication of isolation regions 210, selected portions of semiconductor material 208 can be impurity doped, for example by ion implantation, to form appropriate wells for the active transistor regions. For example, an N-type well can be formed between isolation regions 210 for the fabrication of PMOS transistors.

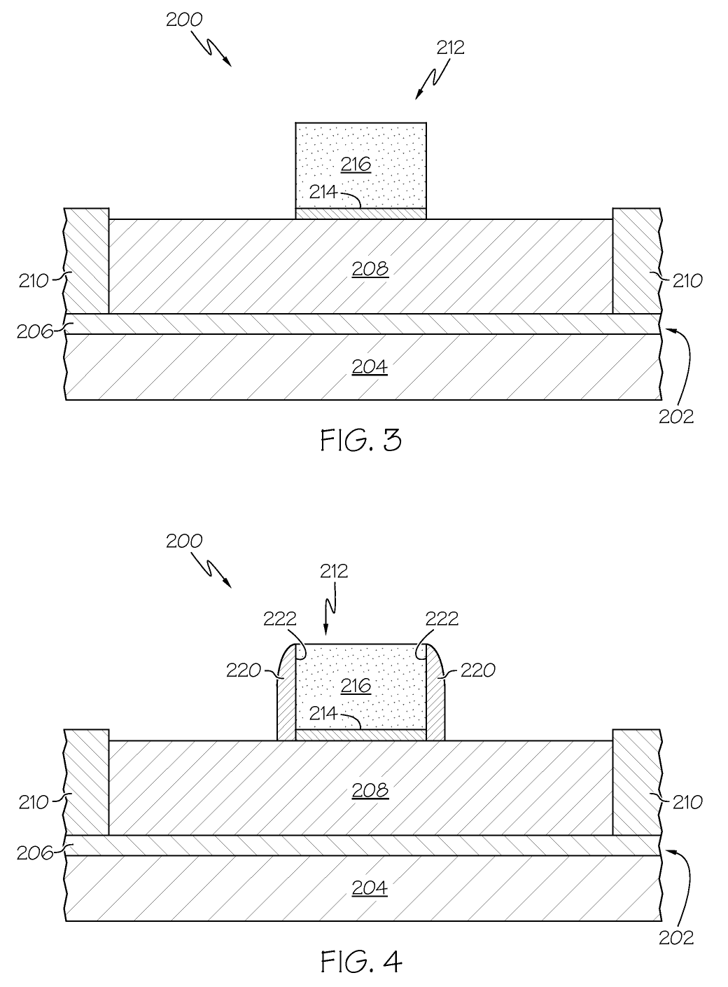

FIG. 3 depicts the state of device structure 200 after formation of a gate structure 212 overlying the layer of semiconductor material 208. This embodiment of gate structure 212 includes a gate insulator 214 and a gate electrode 216 on gate insulator 214. The material used for gate insulator 214 can be a layer of thermally grown silicon dioxide or, alternatively, a deposited insulator such as a silicon oxide, silicon nitride, or the like. Deposited insulators can be deposited, for example, by chemical vapor deposition (CVD), low pressure chemical vapor deposition (LPCVD), or plasma enhanced chemical vapor deposition (PECVD). The gate insulator material preferably has a thickness of about 1-10 nm, although the actual thickness can be determined based on the application of the transistor in the circuit being implemented. The material for gate electrode 216 is formed overlying the gate insulator material. In accordance with one embodiment, the gate electrode material is polycrystalline silicon. The layer of polycrystalline silicon is preferably deposited, e.g., using LPCVD by the hydrogen reduction of silane. A layer of hard mask material (not shown), such as silicon nitride or silicon oxynitride, can be deposited onto the surface of the polycrystalline silicon. The hard mask material can be deposited to a thickness of about 50 nm, also by LPCVD.

FIG. 3 shows gate structure 212 as formed after patterning of the hard mask layer into an etch mask. The underlying gate electrode material and gate insulator material are etched to form gate structure 212. The polycrystalline silicon can be etched in the desired pattern by, for example, reactive ion etching (RIE) using a chlorine or HBr/O₂ chemistry and the hard mask and gate insulating material can be etched, for example, by RIE in a CHF₃, CF₄, or SF₆ chemistry.

After gate structure 212 has been created, spacers 220 are formed adjacent the sidewalls 222 of gate structure 212 (see FIG. 4). Spacers 220 are preferably fabricated in a conventional manner. In this regard, spacers 220 can be formed by conformally depositing a dielectric material over gate structure 212, where the dielectric material is an appropriate insulator, such as silicon oxide and/or silicon nitride, preferably silicon nitride. The dielectric material can be deposited in a known manner by, for example, atomic layer deposition (ALD), CVD, LPCVD, semi-atmospheric chemical vapor deposition (SACVD), or PECVD. The layer of dielectric material is deposited to a thickness so that, after anisotropic etching, spacers 220 formed from the layer have a thickness that is appropriate for the subsequent process steps described below. In typical implementations, the layer of dielectric material is deposited to a thickness of about 5-50 nm. The process continues, in accordance with an exemplary embodiment, with anisotropic etching of the layer of dielectric material to form spacers 220, as illustrated in FIG. 4. The layer of dielectric material can be etched by, for example, RIE using a suitable etching chemistry.

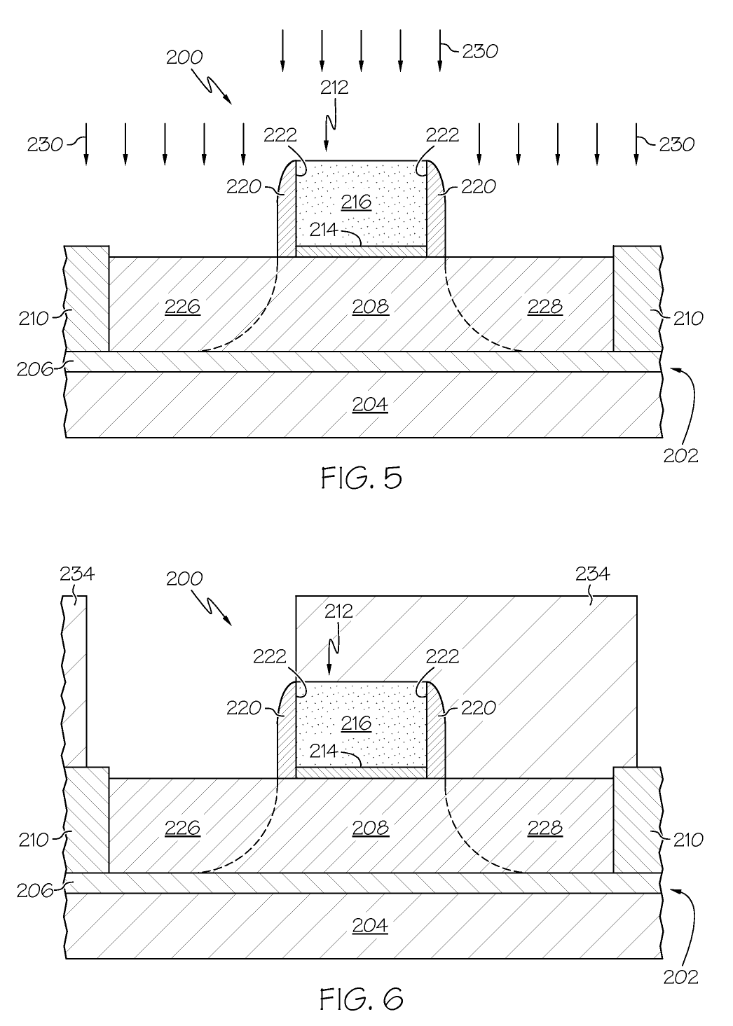

Although other fabrication steps or sub-processes may be performed after the formation of spacers 220, this example continues by forming a source region 226 and a drain region 228 in the layer of semiconductor material 208 (see FIG. 5). For this embodiment, source region 226 and drain region 228 are formed by implanting appropriate conductivity-determining ions of an impurity species into the semiconductor material 208, using gate structure 212, spacers 220, and isolation regions 210 as an implantation mask. In FIG. 5, the arrows 230 represent the ions that are implanted into semiconductor material 208 during this step. For a PMOS transistor the ions can be boron ions. In preferred embodiments, source region 226 and drain region 228 correspond to deep implant regions on either side of gate structure 212—these deep implant regions may abut insulator layer 206 as shown in FIG. 5. As those of skill in the art will appreciate, more than one set of sidewall spacers can be used and more than one ion implantation can be carried out to create source and drain extensions, create halo implants, set threshold voltage, and the like.

Although other fabrication steps or sub-processes may be performed after the formation of source region 226 and drain region 228, this example continues by forming a patterned photoresist layer 234 that overlies drain region, but does not overlie source region 226 (see FIG. 6). Patterned photoresist layer 234 can be formed in a conventional manner using well-known photolithography techniques. For example, patterned photoresist layer 234 can be created by depositing a layer of photoresist material over the exposed features of device structure 200, exposing the photoresist material using a photomask having an appropriate pattern defined therein, and developing the exposed photoresist material to selectively remove portions of the photoresist material. FIG. 6 depicts device structure 200 after the patterned photoresist layer 234 has been developed. As shown, patterned photoresist layer 234 completely covers drain region 228. For the illustrated embodiment, patterned photoresist layer 234 also covers at least a portion of isolation region 210 that is adjacent to drain region 228, and it also covers gate structure 212.

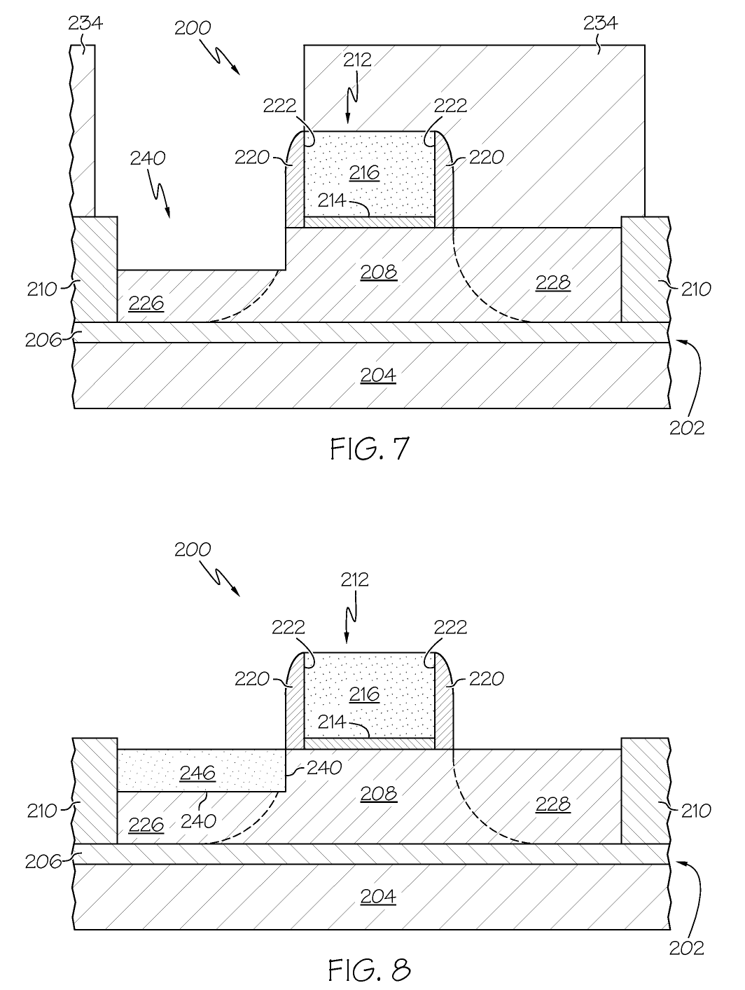

Although other fabrication steps or sub-processes may be performed after the creation of patterned photoresist layer 234, this example continues by etching semiconductor material 208 (see FIG. 7). During the etching step, patterned photoresist layer 234 is used as an etch mask. In practice, one or more of the following features (or portions thereof) might also serve as the etch mask during the etching step: isolation regions 210; spacers 220; or gate structure 212. The etching step creates a source recess 240 (also referred to as a cavity or a trench) in semiconductor material 208; the source recess 240 corresponds to source region 226 because it occupies space formerly devoted to source region 226 and because it is located above the remaining lower portion of source region 226. In preferred embodiments, source recess 240 is formed by anisotropically etching semiconductor material 208, for example, by RIE using a HBr/O₂ chemistry to an appropriate depth of about 50-60 nm. This etching results in a source recess 240 that is self-aligned with the outer sidewall of the exposed spacer 220.

Notably, patterned photoresist layer 234 protects drain region 228 and prevents the portion of semiconductor material 208 corresponding to drain region 228 from being etched. Consequently, source recess 240 is formed during the etching step without creating a drain recess in drain region 228. The formation of asymmetric recesses is depicted in FIG. 7—no recess is created in semiconductor material 208 located on the drain side of device structure 200.

Although other fabrication steps or sub-processes may be performed after the formation of source recess 240, this example continues by removing patterned photoresist layer 234 and at least partially filling source recess 240 with a stress-inducing semiconductor material 246 (see FIG. 8). In FIG. 8, stress-inducing semiconductor material 246 corresponds to (or forms a part of) source region 226, while drain region 228 is void of any stress-inducing semiconductor material. In preferred embodiments, source recess 240 is completely filled with stress-inducing semiconductor material 246, as depicted in FIG. 8. In this embodiment, the stress-inducing semiconductor material is formed by selectively epitaxially growing an appropriate silicon material in source recess 240. As mentioned previously, for an NMOS transistor device, the epitaxially grown semiconductor material may be silicon carbon, and for a PMOS transistor device, the epitaxially grown semiconductor material may be doped silicon germanium.

Depending upon the chosen process technology, stress-inducing semiconductor material 246 may be grown in an undoped state, or it may be in-situ doped (meaning that a suitable dopant is introduced into a host material as that host material is grown). Epitaxially grown in-situ doped silicon material can be utilized so that the material need not be subjected to ion implantation for purposes of doping. For an NMOS transistor device, the in-situ doped material may be phosphorus doped silicon carbon, and for a PMOS transistor device, the in-situ doped material may be boron doped silicon germanium. If stress-inducing semiconductor material 246 is formed in an undoped state, then a subsequent ion implantation step may be performed to implant impurity ions into stress-inducing semiconductor material 246. In practice, both the source and drain sides could be subjected to conventional halo, extension, and other implants.

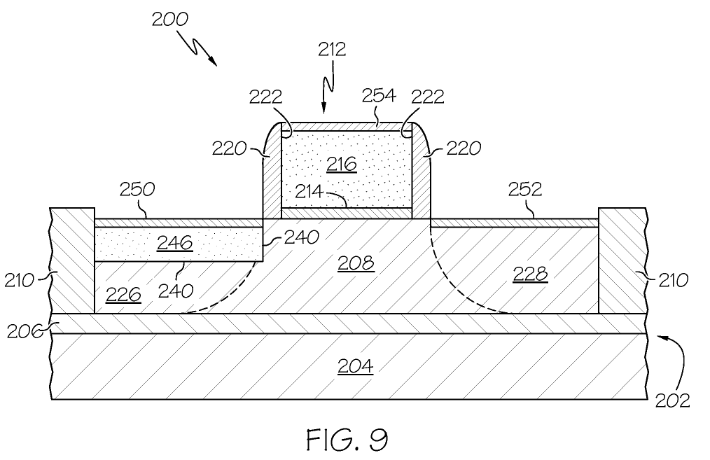

Although other fabrication steps or sub-processes may be performed at this time (e.g., thermal annealing, formation of additional spacers, etc.), this example continues by forming metal silicide contact areas for the source, drain, and gate of device structure 200. More particularly, a source silicide contact area 250 is formed on stress-inducing semiconductor material 246, a drain silicide contact area 252 is formed on drain region 228, and a gate silicide contact area 254 is formed on the polysilicon gate electrode 216 (see FIG. 9). It should be apparent that FIG. 9 depicts device structure 200 after a number of known process steps related to the formation of contacts have been performed. For the sake of brevity, these intermediate steps will not be described in detail. In practice, an appropriate silicidation process is performed to create metal silicide contact areas 250, 252, 254. For example, a layer of silicide-forming metal (not shown) is deposited onto the surfaces of stress-inducing semiconductor material 246, semiconductor material 208, and gate electrode 216. The silicide-forming metal can be deposited, for example, by sputtering to a thickness of about 5-50 nm and preferably to a thickness of about 10 nm. The wafer is then heated, for example by rapid thermal annealing, to form the metal silicide contact areas 250, 252, 254. The silicide-forming metal can be, for example, cobalt, nickel, rhenium, ruthenium, or palladium, or alloys thereof. Any silicide-forming metal that is not in contact with exposed silicon does not react during heating and, therefore, does not form a silicide. This excess metal may be removed by wet etching or any suitable procedure.

Thereafter, any number of known process steps can be performed to complete the fabrication of the MOS transistor device. For the sake of brevity, these process steps and the resulting MOS transistor device are not shown or described here. A MOS transistor device can be manufactured in this manner such that it has an asymmetric profile or arrangement of strain elements. During operation, this asymmetry results in relatively high source-body junction leakage and relatively low drain-body junction leakage, which can provide certain benefits and advantages for analog circuit applications.

While at least one exemplary embodiment has been presented in the foregoing detailed description, it should be appreciated that a vast number of variations exist. It should also be appreciated that the exemplary embodiment or embodiments described herein are not intended to limit the scope, applicability, or configuration of the claimed subject matter in any way. Rather, the foregoing detailed description will provide those skilled in the art with a convenient road map for implementing the described embodiment or embodiments. It should be understood that various changes could be made in the function and arrangement of elements without departing from the scope defined by the claims, which includes known equivalents and foreseeable equivalents at the time of filing this patent application.

What is claimed is:

1. A semiconductor transistor device comprising:
a layer of semiconductor material having a channel region defined therein;
a gate structure overlying the channel region;
a source region in the layer of semiconductor material;
a drain region in the layer of semiconductor material, the channel region located between the source region and the drain region;
a source recess formed in the layer of semiconductor material and located in the source region; and
a stress-inducing semiconductor material located in the source recess, wherein the drain region is void of the stress-inducing semiconductor material.

2. The semiconductor transistor device of claim 1, wherein the stress-inducing semiconductor material increases source-to-body junction leakage of the semiconductor transistor device, relative to drain-to-body leakage of the semiconductor transistor device.

3. The semiconductor transistor device of claim 1, wherein the stress-inducing semiconductor material comprises an epitaxially grown silicon material.

4. The semiconductor transistor device of claim 3, wherein:
the semiconductor transistor device is an NMOS transistor device;
the epitaxially grown silicon material is silicon carbon; and
the silicon carbon imparts a tensile longitudinal stress to the channel region.

5. The semiconductor transistor device of claim 3, wherein:
the semiconductor transistor device is a PMOS transistor device;
the epitaxially grown silicon material is silicon germanium; and
the silicon germanium imparts a compressive longitudinal stress to the channel region.

6. The semiconductor transistor device of claim 3, wherein the epitaxially grown silicon material is an in-situ doped silicon material.

7. A method of fabricating a semiconductor device, the method comprising:
forming a gate structure overlying a layer of semiconductor material;
forming spacers adjacent sidewalls of the gate structure;
forming a source region and a drain region in the layer of semiconductor material;
creating a source recess in the layer of semiconductor material corresponding to the source region without creating a drain recess in the layer of semiconductor material corresponding to the drain region; and
at least partially filling the source recess with a stress-inducing semiconductor material.

8. The method of claim 7, wherein the step of forming the source region and the drain region comprises implanting ions of an impurity species into the layer of semiconductor material, using the gate structure and the spacers as an implantation mask.

9. The method of claim 7, wherein the step of creating the source recess comprises:
forming a patterned photoresist layer that overlies the drain region and does not overlie the source region; and
etching the layer of semiconductor material using the patterned photoresist layer as an etch mask.

10. The method of claim 7, wherein at least partially filling the source recess comprises epitaxially growing a silicon material in the source recess.

11. The method of claim 10, wherein:
the semiconductor device is an NMOS transistor device; and
the step of epitaxially growing the silicon material comprises epitaxially growing silicon carbon in the source recess.

12. The method of claim 10, wherein:
the semiconductor device is a PMOS transistor device; and
the step of epitaxially growing the silicon material comprises epitaxially growing silicon germanium in the source recess.

13. The method of claim 7, further comprising the step of forming a silicide contact area on the stress-inducing semiconductor material.

14. A semiconductor transistor device comprising:
a layer of semiconductor material;
a gate structure overlying the layer of semiconductor material;
a source region in the layer of semiconductor material, the source region comprising a stress-inducing semiconductor material; and
a drain region in the layer of semiconductor material, the drain region being free of the stress-inducing semiconductor material.

15. The semiconductor transistor device of claim 14, further comprising a source recess formed in the layer of semiconductor material, the stress-inducing semiconductor material being located in the source recess.

16. The semiconductor transistor device of claim 14, wherein the stress-inducing semiconductor material comprises an epitaxially grown silicon material.

17. The semiconductor transistor device of claim 16, wherein:
the semiconductor transistor device is an NMOS transistor device; and
the epitaxially grown silicon material is silicon carbon.

18. The semiconductor transistor device of claim 16, wherein:
the semiconductor transistor device is a PMOS transistor device; and
the epitaxially grown silicon material is silicon germanium.

19. The semiconductor transistor device of claim 16, wherein the epitaxially grown silicon material is an in-situ doped silicon material.
